(19) United States
(12) Patent Application Publication
(10) Pub. No.: US 2024/0234582 A1
(43) Pub. Date: Jul. 11, 2024

(54) SEMICONDUCTOR DEVICE INCLUDING A BLOCKING LAYER

(71) Applicant: TAIWAN SEMICONDUCTOR MANUFACTURING COMPANY, LTD., Hsinchu (TW)

(72) Inventors: Wu-Wei TSAI, Hsinchu (TW); Hai-Ching CHEN, Hsinchu (TW); Kai-Wen CHENG, Hsinchu (TW); Yu-Ming LIN, Hsinchu (TW); Chung-Te LIN, Hsinchu (TW)

(73) Assignee: TAIWAN SEMICONDUCTOR MANUFACTURING COMPANY, LTD., Hsinchu (TW)

(21) Appl. No.: 18/151,141

(22) Filed: Jan. 6, 2023

(51) Int. Cl. H01L 29/786; H01L 21/8234; H01L 29/417

(52) U.S. Cl. CPC H01L 29/78696; H01L 21/823412; H01L 21/823418; H01L 29/41733; H01L 29/7869

(57) ABSTRACT

A semiconductor device includes a gate electrode, a gate dielectric located over the gate electrode, a channel layer including a semiconductor material and located over the gate dielectric, blocking layers located over the channel layer, covering portions of channel layer, and spaced apart from each other, buffer layers respectively located over the blocking layers, respectively surrounded by the blocking layers, and including a material that receives hydrogen, and source/drain contacts respectively located over the buffer layers and respectively surrounded by the buffer layers.

### BACKGROUND

With the advancement in semiconductor manufacturing technology, how to fabricate transistor devices in a back end of line (BEOL) portion of semiconductor device fabrication, instead of a front end of line (FEOL) portion of the semiconductor device fabrication, has become a topic of interest in the industry. When attempting to achieve such a goal, many issues may arise, such as device performance degradation after a thermal-related process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 12 are schematic views illustrating intermediate stages of the method depicted in FIG. 1 in accordance with some embodiments.

FIG. 13 is a flow diagram illustrating a method for manufacturing a semiconductor device in accordance with some embodiments.

FIGS. 14 to 19 are schematic views illustrating intermediate stages of the method depicted in FIG. 13 in accordance with some embodiments.

FIG. 20 is a flow diagram illustrating a method for manufacturing a semiconductor device in accordance with some embodiments.

FIGS. 21 to 33 are schematic views illustrating intermediate stages of the method depicted in FIG. 20 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to a semiconductor device where interface engineering at a source and a drain is introduced to improve the device stability during a thermal-related process in semiconductor device fabrication, e.g., a process for controlling deposition temperature of source/drain metal layers or dielectric layers, an annealing process, etc. In some embodiments, the semiconductor device is a transistor that includes a channel layer. In some embodiments, the transistor may be a thin-film transistor (TFT) which is a type of metal-oxide-semiconductor field-effect transistor (MOSFET), and may be fabricated by forming the channel layer, metallic contacts and a dielectric layer over a substrate. The TFTs may be utilized in several commercial applications such as large-area displays, high-resolution displays, three-dimensional displays, flexible circuits, printable circuits, transparent circuits, biochemistry sensors, photon sensors, etc. Generally speaking, a TFT is similar to a MOSFET in structure, and includes a gate terminal, a source terminal and a drain terminal. A semiconductor layer known as a channel layer is deposited to contact the source terminal and the drain terminal.

Different materials have been proposed to be used for fabricating TFTs, and oxide semiconductors such as indium gallium zinc oxide (IGZO) may be used to form some parts of the TFTs (e.g., the channel layer). The fabrication of such devices may be integrated in a back end of line (BEOL) portion of semiconductor device fabrication, instead of a front end of line (FEOL) portion of the semiconductor device fabrication. In some embodiments, when integrating the fabrication of TFTs in the BEOL portion, the semiconductor fabrication process may be implemented at a relatively lower temperature, and therefore the undesirable effect of damaging devices that are already fabricated, such as transistors fabricated in the FEOL portion, may be reduced.

In one TFT structure, two source/drain contacts may be disposed in contact with a channel layer. The source/drain contacts may refer to contacts for a source and/or a drain, individually or collectively dependent upon the context. It is noted that the channel layer of the TFT fabricated in the BEOL portion may be sensitive to hydrogen gas and/or free hydrogen atoms, which may be generated or used in many processes, such as chemical vapor depositions (CVD). Upon annealing, hydrogen (e.g., hydrogen gas and/or free hydrogen atoms) may be incorporated into the deposited material, and may diffuse from the source/drain contacts to reach and react with the channel layer, a phenomenon known as hydrogen diffusion or H-diffusion. It is noted that in other steps of the fabrication process (e.g., deposition of oxide material), hydrogen gas and/or hydrogen atoms may also be introduced into the channel layer, thereby doping the channel layer. With different dimensions of the channel layer, hydrogen diffusion may cause different degrees of threshold voltage shift, which might adversely affect properties and stabilities of TFTs.

In order to mitigate the adverse effects of hydrogen diffusion, a buffer layer is provided around each of the source/drain contacts so as to prevent hydrogen gas and/or hydrogen atoms from diffusing from the source/drain contacts or other devices into the channel layer. However, in forming the buffer layers around the source/drain contacts, elements of the buffer layer may intermix with the channel layer, which may introduce a disproportionate chemical distribution of the channel layer in comparison to what would have been intended in the fabrication. Moreover, ions may diffuse from the buffer layer into the channel layer (i.e., inter-diffusion between the buffer layer and the channel layer) which might adversely affect performance of the resultant TFT.

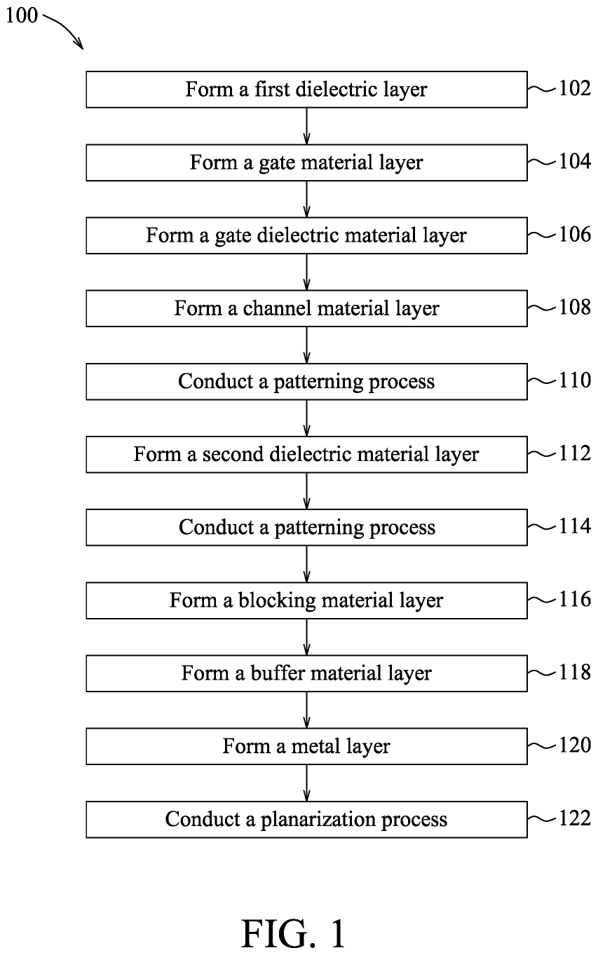

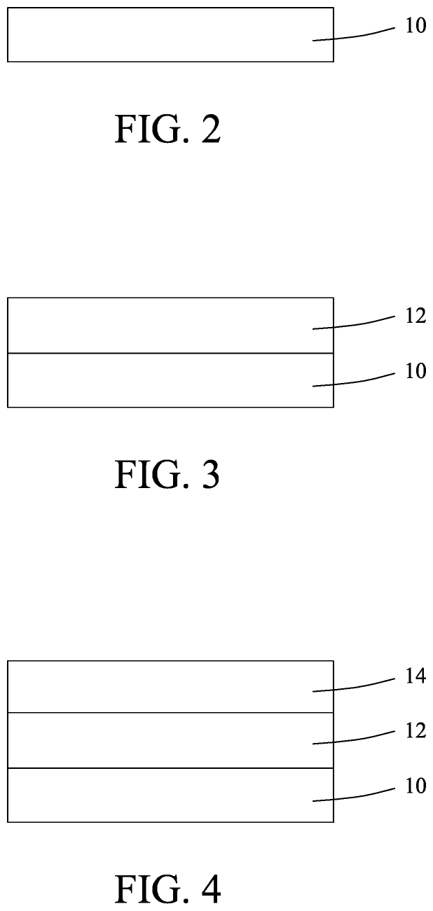

FIG. 1 is a flow diagram illustrating a method 100 for manufacturing a semiconductor device that includes a transistor in accordance with some embodiments. FIGS. 2 to 12 illustrate schematic views of a semiconductor device at some intermediate stages of the method 100 in accordance with some embodiments. Additional steps can be provided before, after or during the method 100, and some of the steps described herein may be replaced by other steps or be eliminated. Similarly, further additional features may be present in the semiconductor device, and/or features present may be replaced or eliminated in additional embodiments.

Referring to FIG. 1 and the example illustrated in FIG. 2, the method 100 begins at step 102, where a first dielectric layer 10 is formed. In some embodiments, the first dielectric layer 10 may serve as an interlayer dielectric (ILD) layer, and may include materials such as, but not limited to, silica (SiO₂), hafnium silicate (HfSiO₄), zirconium silicate (ZrSiO₄), or combinations thereof. In alternative embodiments, the first dielectric layer 10 may include, but not limited to, epoxy resin, acrylic resin, phenol resin, polyimide, benzocyclobutene (BCB), polybenzooxazole (PBO), other suitable polymer-based dielectric materials, or combinations thereof. Other suitable dielectric materials for forming the first dielectric layer 10 are within the contemplated scope of the present disclosure.

In some embodiments, step 102 may be implemented using, for example, but not limited to, CVD, physical vapor deposition (PVD), sputtering, other suitable techniques, or combinations thereof. In some embodiments, the first dielectric layer 10 may be a single material layer. In alternative embodiments, the first dielectric layer 10 may be constituted by multiple films made of different materials. In some embodiments, step 102 may be implemented in the BEOL portion of semiconductor device fabrication.

Referring to FIGS. 1 and 3, the method 100 then proceeds to step 104, where a gate material layer 12 is formed on the first dielectric layer 10. The gate material layer 12 may include a metal material, a metal compound, polycrystalline silicon, or doped silicon. Other materials suitable for forming the gate material layer 12 are within the scope of the present disclosure. The metallic material may include, for example, but not limited to, silver (Ag), aluminum (Al), copper, tungsten, nickel (Ni), other suitable materials, alloys thereof, or combinations thereof. The metal compound may include, for example, but not limited to, titanium nitride (TiN), tantalum nitride (TaN), metal silicide, other suitable materials, or combinations thereof.

In some embodiments, the gate material layer 12 may be deposited by, for example, but not limited to, PVD, CVD, sputtering, plating, other suitable techniques, or combinations thereof.

Referring to FIGS. 1 and 4, the method 100 then proceeds to step 106, where a gate dielectric material layer 14 is formed on the gate material layer 12. The gate dielectric material layer 14 may include a high-k dielectric material such as, but not limited to, silicon oxide (SiO₂), silicon nitride (Si₃N₄), silicon oxynitride (SiOₓN_{y}), aluminum oxide (Al₂O₃), hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium silicate, zirconium aluminate, zirconium oxide, titanium oxide, hafnium oxide-zirconium oxide (HfOₓ—ZrOₓ) alloy, hafnium dioxide-alumina (HfO₂—Al₂O₃) alloy, hafnium oxide-lanthanum oxide (HfO—LaOₓ) alloy, hafnium oxide-silicon oxide (HfOₓ—SiOₓ) alloy, hafnium oxide-strontium oxide (HfOₓ—SrO) alloy, cerium oxide (CeOₓ) doped with hafnium-zirconium oxide (HZO), or combinations thereof. Other suitable dielectric materials for forming the gate dielectric material layer 14 are within the contemplated scope of the present disclosure.

In some embodiments, the gate dielectric material layer 14 may be formed by, for example, but not limited to, sputtering, CVD, PVD, atomic layer deposition (ALD), plasma-enhanced ALD, molecular beam epitaxy (MBE), other suitable techniques, or combinations thereof. In some embodiments, the gate dielectric material layer 14 may include one or more layers, each being made using one or more of the dielectric materials mentioned above.

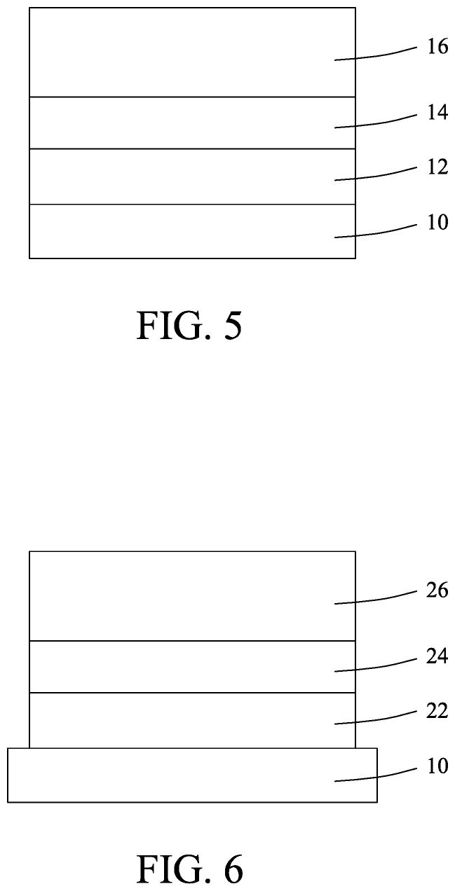

Referring to FIGS. 1 and 5, the method 100 then proceeds to step 108, where a channel material layer 16 is formed on the gate dielectric material layer 14. The channel material layer 16 may include an oxide semiconductor material such as, but not limited to, indium zinc oxide (IZO), indium gallium oxide (IGO), indium gallium zinc oxide (IGZO), tungsten-doped indium oxide (IWO), tungsten-doped indium zinc oxide (IWZO), indium gallium zinc tin oxide (IGZTO), zinc oxide (ZnO), indium tin oxide (ITO), gallium oxide (GaOₓ), indium oxide (InOₓ), or the like. In alternative embodiments, the channel material layer 16 may further include, for example, but not limited to, amorphous silicon, crystalline silicon (either polycrystalline silicon or monocrystalline silicon), or the like. Other suitable materials for forming the channel material layer 16 are within the contemplated scope of the present disclosure.

In some embodiments, step 108 may be implemented using CVD, PVD, ALD, plasma-enhanced CVD (PECVD), epitaxial growth, or other suitable techniques

Referring to FIGS. 1 and 6, the method 100 then proceeds to step 110, where a patterning process is conducted so as to form a pattern in the gate material layer 12, the gate dielectric material layer 14, and the channel material layer 16. As a result, a patterned gate material layer, a patterned gate dielectric material layer and a patterned channel material layer are formed to serve as a gate electrode 22, a gate dielectric 24 and a channel layer 26 of a transistor, respectively. It is noted that in some embodiments, the gate electrode 22 and the gate dielectric 24 may cooperatively form a gate stack, and the gate dielectric 24 is disposed between the gate electrode 22 and the channel layer 26.

In some embodiments, the patterning process in step 110 includes a photolithography process, an etching process, and a stripping process. In some embodiments, the photolithography process may include, for example, but not limited to, coating a photoresist layer on the channel material layer 16, then soft-baking, then exposing the photoresist layer through a photomask (not shown in the drawings), then post-exposure baking, then developing the photoresist layer, followed by hard-baking, so as to form a patterned photoresist (not shown in the drawings).

Afterward, the etching process may be implemented by etching the gate material layer 12, the gate dielectric material layer 14 and the channel material layer 16 through the patterned photoresist using, for example, but not limited to, a dry etching process, a wet etching process, other suitable processes, or combinations thereof.

After the etching process is completed, the stripping process is conducted for stripping the patterned photoresist. Based on the materials of the patterned photoresist, a number of suitable chemical solutions may be used to strip the patterned photoresist.

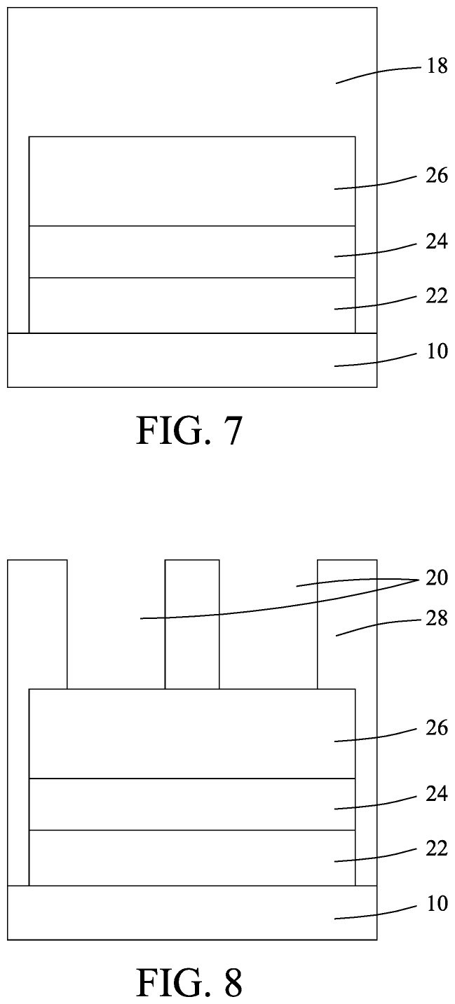

Referring to FIGS. 1 and 7, the method 100 then proceeds to step 112, where a second dielectric material layer 18 is formed on the first dielectric layer 10, the gate electrode 22, the gate dielectric 24 and the channel layer 26. The materials and techniques used for forming the second dielectric material layer 18 are similar to those used for forming the first dielectric layer 10 as described in step 102, and the details thereof are omitted herein for the sake of brevity. In some embodiments, the second dielectric material layer 18 may be a single material layer. In alternative embodiments, the second dielectric material layer 18 may be constituted by multiple films made of different materials that are suitable for forming the first dielectric layer 10. It is noted that a chemical-mechanical planarization (CMP) process or another suitable process is performed to planarize a top surface of the second dielectric material layer 18.

Referring to FIGS. 1 and 8, the method 100 then proceeds to step 114, where a patterning process is conducted to pattern the second dielectric material layer 18. The patterning process in this step may be implemented using a technique as described in step 110 such that portions of the second dielectric material layer 18 are removed in a top-down direction to expose portions of the channel layer 26. As a result, two trenches 20 are formed in the second dielectric material layer 18, thereby obtaining a second dielectric layer 28, and the portions of the channel layer 26 are exposed through the trenches 20.

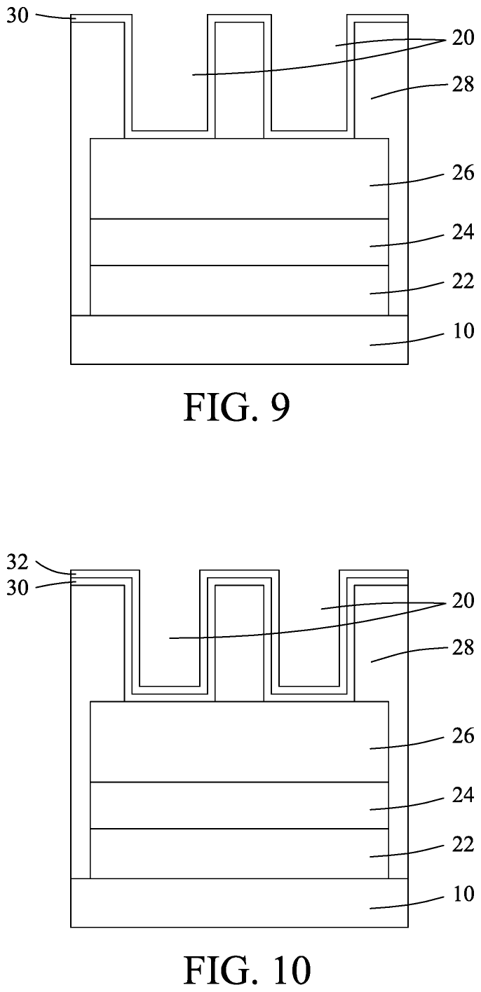

Referring to FIGS. 1 and 9, the method 100 then proceeds to step 116, where a blocking material layer 30 is conformally formed on the second dielectric layer 28 and the channel layer 26 along inner surfaces of the trenches 20. The blocking material layer 30 may include titanium nitride (TiN), tantalum nitride (TaN), titanium (Ti), nickel (Ni), aluminum (Al), ruthenium (Ru), or combinations thereof. Other suitable materials for forming the blocking material layer 30 are within the contemplated scope of the present disclosure. In some embodiments, the blocking material layer 30 may be formed using ALD, PVD, CVD, plating, or other suitable deposition techniques. A thickness of the blocking material layer 30 may be in a range of from about 1 to about 10 nanometers, although the blocking material layer 30 may have a wider or narrower thickness based on the product to be fabricated. In some cases, if the thickness of the blocking material layer 30 is smaller than 1 nanometer, an effect of preventing intermixing and/or inter-diffusion between a later-formed buffer layer and the channel layer 26 may diminish, and if the thickness of the blocking material layer 30 is greater than 10 nanometers, there may be a waste of material and the blocking material layer 30 may occupy too much space of the trenches 20.

Referring to FIGS. 1 and 10, the method 100 then proceeds to step 118, where a buffer material layer 32 is conformally formed on the blocking material layer 30 along surfaces of the blocking material layer 30 in the trenches 20. The buffer material layer 32 may include indium oxide (InOₓ, e.g., In₂O₃), indium zinc oxide (IZO), indium tin oxide (ITO), zinc tin oxide (ZTO), indium gallium zinc oxide (IGZO), gallium oxide (GaOₓ, e.g., Ga₂O₃), crystalline InGaZnOₓ (c-IGZO), a semiconductor material including indium, gallium, silicon, zinc, and oxide (IGSZO, InGaSiZnOₓ), ZrₓNi_{y}, zinc oxide (ZnO), tungsten-doped indium oxide (IWO), or combinations thereof. To be specific, ZrₓNi_{y} is a metal compound including Zr (zirconium) and Ni (nickel). In some embodiments, the buffer material layer 32 may include a material that receives hydrogen. Other suitable materials for forming the buffer material layer 32 are within the contemplated scope of the present disclosure. In some embodiments, the buffer material layer 32 may be formed using ALD, PVD, CVD, plating, or other suitable deposition techniques. A thickness of the buffer material layer 32 may be in a range of from about 1 to about 10 nanometers, although the buffer material layer 32 may have a wider or narrower thickness based on the product to be fabricated. In some cases, if the thickness of the buffer material layer 32 is smaller than 1 nanometer, an effect of preventing hydrogen gas and/or hydrogen atoms from diffusing from a later-formed source/drain contacts into the channel layer 26 may diminish, and if the thickness of the buffer material layer 32 is greater than 10 nanometers, there may be a waste of material and there may be insufficient space left for forming the source/drain contacts.

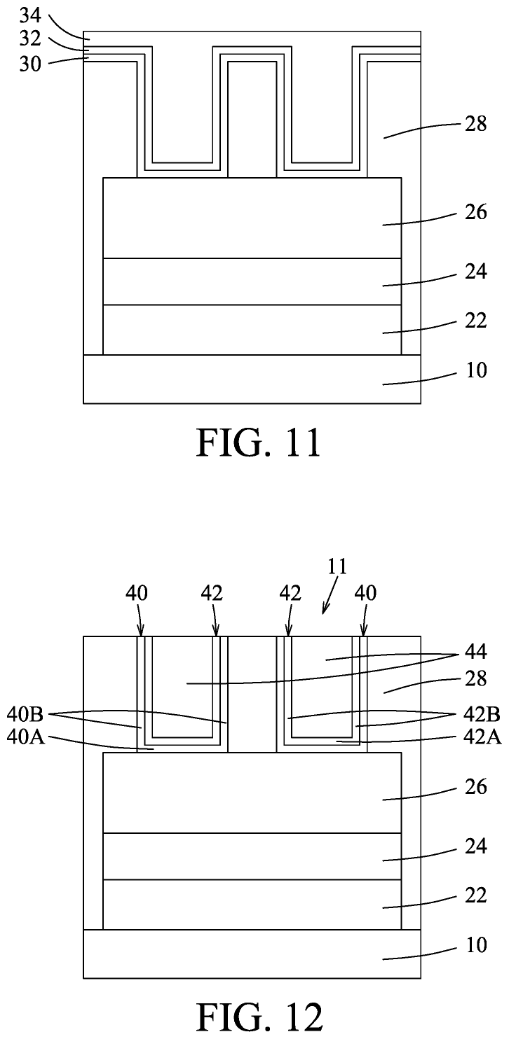

Referring to FIGS. 1 and 11, the method 100 then proceeds to step 120, where a metal layer 34 is formed on the buffer material layer 32 to fill the trenches 20 shown in FIG. 10. The metal layer 34 may include metals such as tungsten (W), ruthenium (Ru), copper (Cu), nickel (Ni), titanium (Ti), aluminum (Al), indium tin oxide (ITO), or combinations thereof. Other suitable materials for forming the metal layer 34 are within the contemplated scope of the present disclosure. The metal layer 34 may be formed using PVD, CVD, ALD, plating, or other suitable deposition techniques.

Referring to FIGS. 1 and 12, the method 100 then proceeds to step 122, where a planarization process such as a CMP process, or another suitable technique is conducted to remove excesses of the blocking material layer 30, the buffer material layer 32 and the metal layer 34. In some embodiments, the CMP process may be performed to the point that the second dielectric layer 28 is exposed. At this stage, the blocking material layer 30 remaining in the trenches 20, which is shown in FIG. 11, may serve as two U-shaped blocking layers 40 of a transistor 11, the buffer material layer 32 remaining in the trenches 20 may serve as two U-shaped buffer layers 42 of the transistor 11, and the metal layer 34 remaining in the trenches 20 may serve as two source/drain contacts 44 of the transistor 11. In this manner, the source/drain contacts 44 are formed in the trenches 20 so as to permit each of the source/drain contacts 44 to be surrounded by a respective one of the buffer layers 42 and a respective one of the blocking layers 40. It is noted that the formation of the source/drain contacts 44 creates a current-carrying channel between two regions of the channel layer 26 underneath the source/drain contacts 44. In some embodiments, since the transistor 11 may be fabricated in the BEOL portion, the source/drain contacts 44 may be configured to be connected to one of a number of metal contact lines (M0, M1, . . . , Mx) that interconnects different layers in a part of a BEOL stack.

FIG. 12 illustrates a semiconductor device in accordance with some embodiments. The semiconductor device includes the first dielectric layer 10, the second dielectric layer 28, and the transistor 11 formed between the first dielectric layer 10 and the second dielectric layer 28. In some embodiments, each of the first dielectric layer 10 and the second dielectric layer 28 may serve as an ILD layer fabricated in the BEOL portion.

In some embodiments, the transistor 11 may be a TFT that may be fabricated in the BEOL portion, but is not limited as such. The transistor 11 includes the gate electrode 22, the gate dielectric 24 located over the gate electrode 22, the channel layer 26 located over the gate dielectric 24, the blocking layers 40 located over the channel layer 26, covering the portions of the channel layer 26 and spaced apart from each other, the buffer layers 42 respectively located over the blocking layers 40 and respectively surrounded by the blocking layers 40, and the source/drain contacts 44 respectively located over the buffer layers 42 and respectively surrounded by the buffer layers 42.

Each of the buffer layers 42 includes an interconnecting buffer section 42A that is in contact with a lower surface of the corresponding one of the source/drain contacts 44, and two extending buffer sections 42B that respectively extend from two opposite ends of the interconnecting buffer section 42A to be respectively in contact with two opposite surfaces of the corresponding one of the source/drain contacts 44. It is noted that in order to ensure that the transistor 11 functions normally, the buffer layers 42 are disposed to be spaced apart from each other.

Each of the blocking layers 40 includes an interconnecting blocking section 40A that is in contact with the channel layer 26 and the interconnecting buffer section 42A of the corresponding one of the buffer layers 42, and two extending blocking sections 40B that respectively extend from two opposite ends of the interconnecting blocking section 40A to be respectively in contact with the extending buffer sections 42B of the corresponding one of the buffer layers 42.

In some embodiments (e.g., as shown in FIG. 12), the source/drain contacts 44 are located over the channel layer 26, and the gate electrode 22 and the gate dielectric 24 are located below the channel layer 26. This structure of the transistor 11 is typically referred to as a front-contacted, back-gate structure. It is noted that in relevant fields, the terms “front” and “top” may be used interchangeably and the terms “back” and “bottom” may be used interchangeably. That is, the structure of the transistor 11 may also be referred to as a top-contacted, bottom-gate structure.

It is noted that, with the provision of the buffer layers 42, which are disposed to separate the source/drain contacts 44 from the channel layer 26, the structure of the transistor 11 as described above may offer a number of advantages. For example, the hydrogen gas and/or free hydrogen atoms moving away from the source/drain contacts 120 may be received by the buffer layers 42 instead of the channel layer 26, and may therefore reduce the potential hydrogen diffusion phenomenon and associated adverse effects. In some embodiments, the buffer layers 42 may contain hydrogen therein, and the channel layer 26 may contain no hydrogen therein.

In addition, with the provision of the blocking layer 40, which are disposed to separate the buffer layers 42 from the channel layer 26, elements of the buffer layers 42 can be blocked from intermixing with the channel layer 26, so that a chemical distribution of the channel layer 26 can be maintained as intended. Moreover, the blocking layers 40 disposed between the channel layer 26 and the buffer layers 42 can prevent ions from diffusing from the buffer layers 42 into the channel layer 26 (i.e., prevent inter-diffusion between the buffer layers 42 and the channel layer 26), so that performance of the transistor 11 may not be adversely affected.

In alternative embodiments, the steps of the method 100 for manufacturing of the semiconductor device shown in FIG. 1 may be slightly altered. For example, additional buffer layers may be provided to be located over the buffer layer and to respectively surround the source/drain contacts 44, so as to boost the effect of reducing the potential hydrogen diffusion phenomenon. Moreover, additional blocking layers may be provided to respectively surround the additional buffer layers, so as to prevent intermixing and/or inter-diffusion between the additional buffer layers and the channel layer 26.

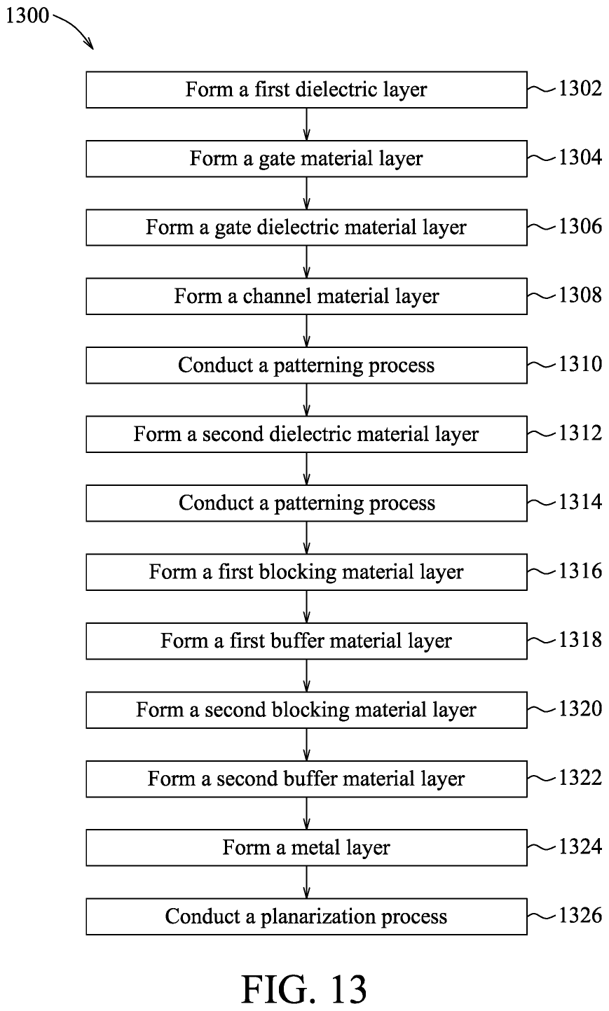

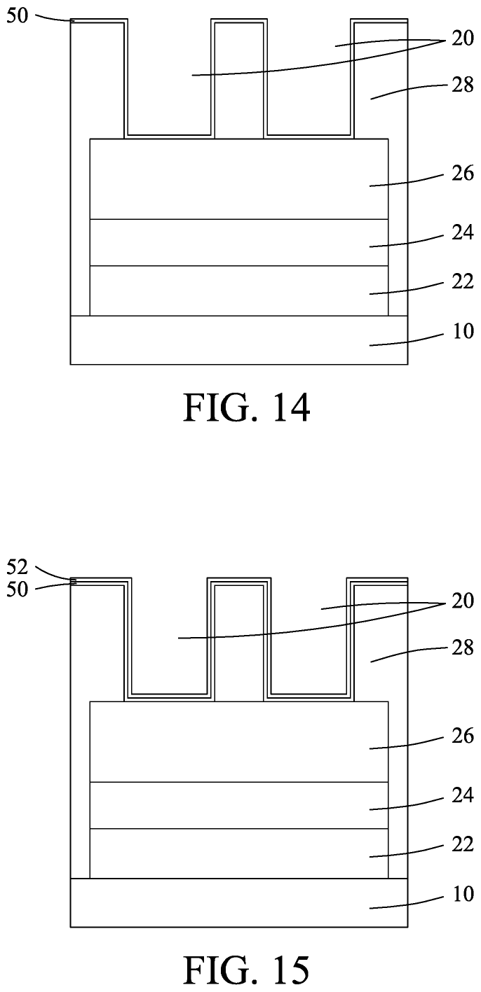

Referring to FIG. 13 that illustrates a method 1300 for manufacturing a semiconductor device in accordance with some embodiments, additional steps of forming another blocking material layer and forming another buffer material layer are sequentially performed after forming a buffer material layer on a blocking material layer (similar to step 118 of the method 100). Then, a metal layer is formed on said another buffer material layer followed by a planarization process (similar to steps 120 and 122 of the method 100) so as to form the semiconductor device that includes a transistor. FIGS. 14 to 19 illustrate schematic views of the intermediate stages of the method 1300.

It is noted that first seven steps of the method 1300 shown in FIG. 13 are generally similar to those of the method 100 shown in FIG. 1. That is to say, the operations of steps 1302, 1304, 1306, 1308, 1310, 1312 and 1314 may be performed in a manner similar to steps 202, 204, 206, 208, 210, 212 and 214 respectively so as to fabricate the structure as shown in FIG. 8. As such, the details regarding steps 1302, 1304, 1306, 1308, 1310, 1312 and 1314 are omitted herein for the sake of brevity.

Referring to FIGS. 13 and 14, after step 1314, the method 1300 proceeds to step 1316, where a first blocking material layer 50 is conformally formed on the second dielectric layer 28 and the channel layer 26 along inner surfaces of the trenches 20. The materials and techniques used for forming the first blocking material layer 50 are similar to those used for forming the blocking material layer 30 as described in step 116 of the method 100 shown in FIG. 1, and the details thereof are omitted herein for the sake of brevity. Step 1316 of the method 1300 is different from step 116 of the method 100 in that a thickness of the first blocking material layer 50 may be smaller than that of the blocking material layer 30. In some embodiments, the thickness of the first blocking material layer 50 may be in a range of from about 1 to about 5 nanometers.

Referring to FIGS. 13 and 15, the method 1300 then proceeds to step 1318, where a first buffer material layer 52 is conformally formed on the first blocking material layer 50 along surfaces of the first blocking material layer 50 in the trenches 20. The materials and techniques used for forming the first buffer material layer 52 are similar to those used for forming the buffer material layer 32 as described in step 118 of the method 100 shown in FIG. 1, and the details thereof are omitted herein for the sake of brevity. Step 1318 of the method 1300 is different from step 118 of the method 100 in that a thickness of the first buffer material layer 52 may be smaller than that of the buffer material layer 32. In some embodiments, the thickness of the first buffer material layer 52 may be in a range of from about 1 to about 5 nanometers.

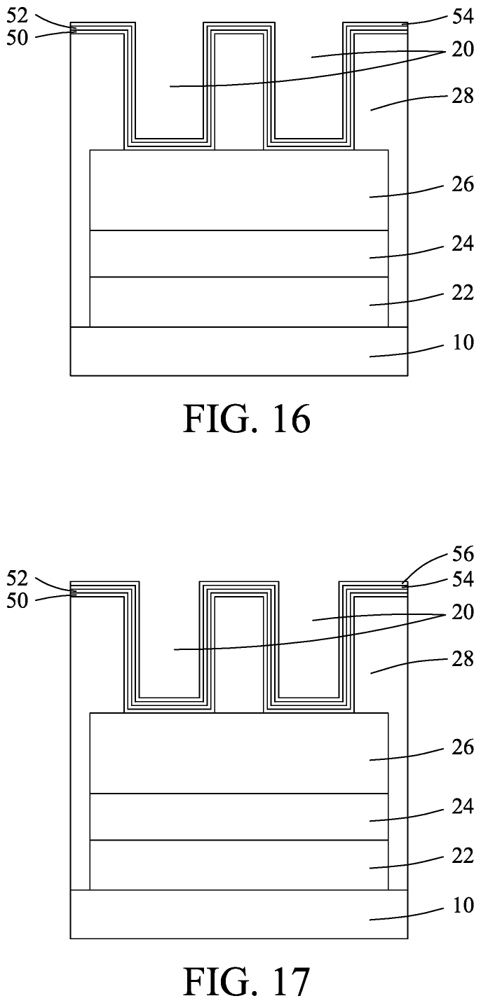

Referring to FIGS. 13 and 16, the method 1300 then proceeds to step 1320, where a second blocking material layer 54 is conformally formed on the first buffer material layer 52 along surfaces of the first buffer material layer 52 in the trenches 20. The materials and techniques used for forming the second blocking material layer 54 are similar to those used for forming the blocking material layer 30 as described in step 116 of the method 100 shown in FIG. 1, and the details thereof are omitted herein for the sake of brevity. In some embodiments, a thickness of the second blocking material layer 54 may be in a range of from about 1 to about 5 nanometers.

Referring to FIGS. 13 and 17, the method 1300 then proceeds to step 1322, where a second buffer material layer 56 is conformally formed on the second blocking material layer 54 along surfaces of the second blocking material layer 54 in the trenches 20. The materials and techniques used for forming the second buffer material layer 56 are similar to those used for forming the buffer material layer 32 as described in step 118 of the method 100 shown in FIG. 1, and the details thereof are omitted herein for the sake of brevity. In some embodiments, a thickness of the second buffer material layer 56 may be in a range of from about 1 to about 5 nanometers.

In comparison with a semiconductor structure shown in FIG. 10, because additional layers (i.e., the second blocking material layer 54 and the second buffer material layer 56) are formed in the trenches 20, the thickness of each of the first and second blocking material layers 50, 54 and the first and second buffer material layers 52, 56 is reduced (i.e., not greater than about 5 nanometers), so as not to occupy the space left for forming source/drain contacts in the trenches 20.

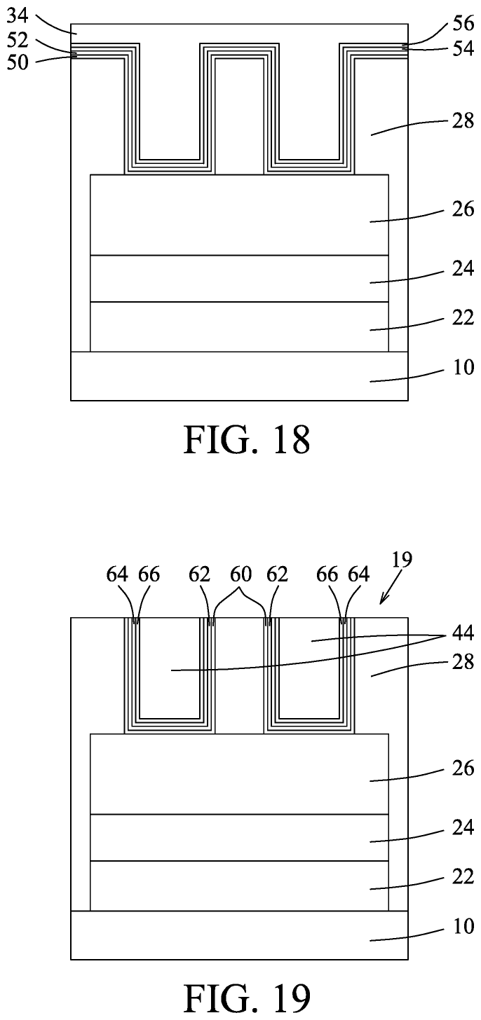

Referring to FIGS. 13 and 18, the method 1300 then proceeds to step 1324, where a metal layer 34 is formed on the second buffer material layer 56 to fill the trenches 20 shown in FIG. 17 along surfaces of the second buffer material layer 56 shown in FIG. 17. The materials and techniques used for forming the metal layer 34 are similar to those used for forming the metal layer 34 as described in step 120 of the method 100 shown in FIG. 1, and the details thereof are omitted herein for the sake of brevity.

Referring to FIGS. 13, 17, 18 and 19, the method 1300 then proceeds to step 1326, where a planarization process such as a CMP process, or another suitable technique is conducted to remove excesses of the first blocking material layer 50, the first buffer material layer 52, the second blocking material layer 54, the second buffer material layer 56 and the metal layer 34. In some embodiments, the CMP process may be performed to the extent that the second dielectric layer 28 is exposed. At this stage, the first blocking material layer 50 remaining in the trenches 20 shown in FIG. 18 may serve as two U-shaped first blocking layers 60 of a transistor 19, the first buffer material layer 52 remaining in the trenches 20 may serve as two U-shaped first buffer layers 62 of the transistor 19, the second blocking material layer 54 remaining in the trenches 20 may serve as two U-shaped second blocking layers 64 of the transistor 19, the second buffer material layer 56 remaining in the trenches 20 may serve as two U-shaped second buffer layers 66 of the transistor 19, and the metal layer 34 remaining in the trenches 20 may serve as two source/drain contacts 44 of the transistor 19. In this manner, the source/drain contacts 44 are formed in the trenches 20 so as to permit each of the source/drain contacts 44 to be surrounded by a respective one of the second buffer layers 66, a respective one of the second blocking layers 64, a respective one of the first buffer layers 62, and a respective one of the first blocking layers 60.

Similar to the semiconductor device shown in FIG. 12, a semiconductor device illustrated in FIG. 19 includes the first dielectric layer 10, the second dielectric layer 28, and the transistor 19 formed between the first dielectric layer 10 and the second dielectric layer 28. In some embodiments, the transistor 19 may be a TFT that may be fabricated in the BEOL portion, but is not limited as such. The transistor 19 includes the gate electrode 22, the gate dielectric 24 located over the gate electrode 22, the channel layer 26 located over the gate dielectric 24, the first blocking layers 60 located over the channel layer 26 and spaced apart from each other, the first buffer layers 62 respectively surrounded by the first blocking layers 60, the second blocking layers 64 respectively surrounded by the first buffer layers 62, the second buffer layers 66 respectively surrounded by the second blocking layers 64, and the source/drain contacts 44 respectively surrounded by and respectively in contact with the second buffer layers 66. The transistor 19 is similar to the transistor 11 of FIG. 12, and differences between the transistor 19 and the transistor 11 reside in that, other than the first buffer layers 62 and the first blocking layers 60, the source/drain contacts 44 are further surrounded by the second buffer layers 66 (i.e., additional buffer layers), and the second blocking layers 64 (i.e., additional blocking layers), so that the effects of reducing the potential hydrogen phenomenon and preventing intermixing and inter-diffusion can be further promoted.

Thus, the method 1300 for manufacturing the semiconductor device shown in FIG. 19 is completed. In alternative embodiments, other suitable methods may also be applied for forming the semiconductor device shown in FIG. 19. In yet alternative embodiments, additional features may be added to the semiconductor device shown in FIG. 19, and some features of the semiconductor device shown in FIG. 19 may be modified, replaced, or eliminated without departing from the spirit and scope of the present disclosure.

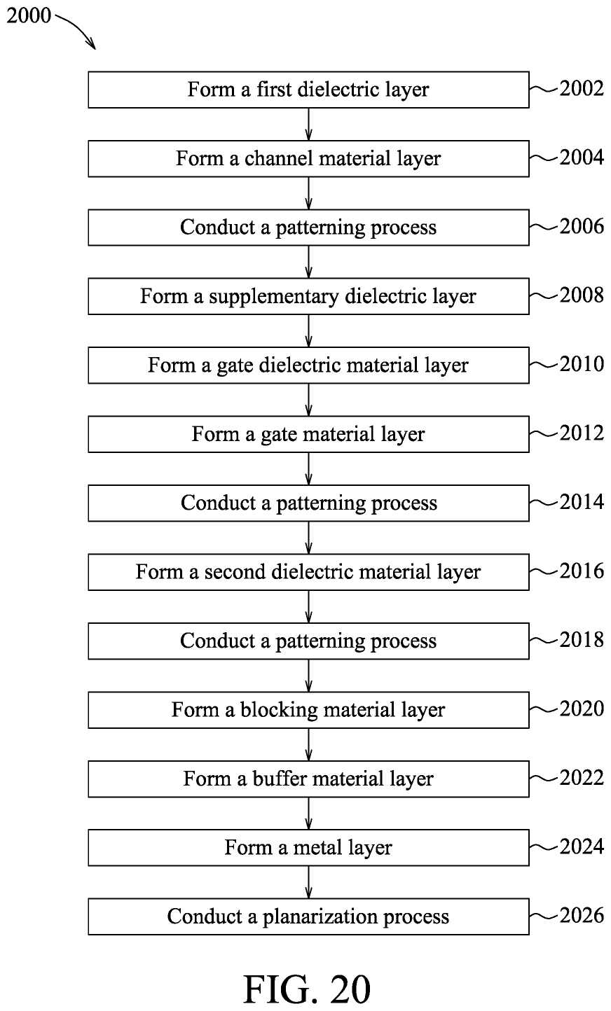

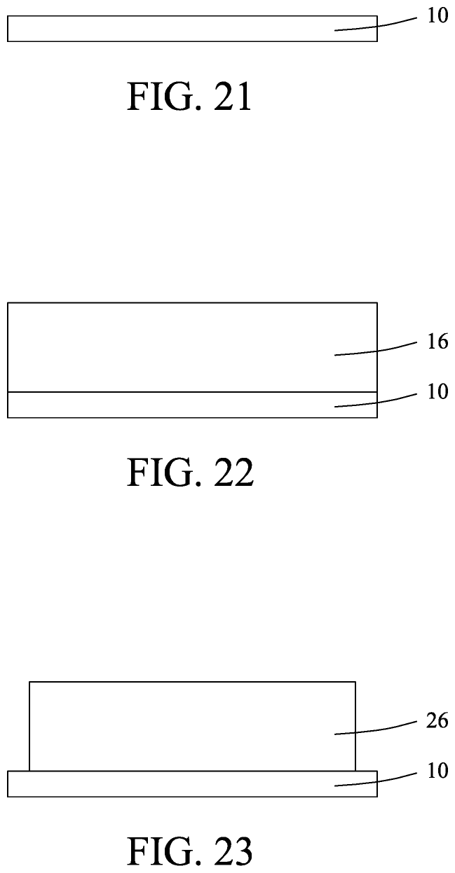

FIG. 20 illustrates a method 2000 for manufacturing a semiconductor device that includes a transistor which has a front-contacted, front-gate structure in accordance with some embodiments. FIGS. 21 to 33 illustrate schematic views of the intermediate stages of the method 2000.

Referring to FIGS. 20 and 21, the method 2000 begins at step 2002, where a first dielectric layer 10 is formed. In some embodiments, the first dielectric layer 10 may serve as an ILD layer. The materials and techniques used for forming the first dielectric layer 10 may be similar to those used for forming the first dielectric layer 10 as described in step 102, and the details thereof are omitted herein for the sake of brevity.

Referring to FIGS. 20 and 22, the method 2000 then proceeds to step 2004, where a channel material layer 16 is formed on the first dielectric layer 10. The materials and techniques used for forming the channel material layer 16 may be similar to those used for forming the channel material layer 16 as described in step 108, and the details thereof are omitted herein for the sake of brevity.

Referring to FIGS. 20 and 23, the method 2000 then proceeds to step 2006, where a patterning process is conducted so as to form a pattern for the channel material layer 16. As a result, a patterned channel material layer is formed to serve as a channel layer 26 of a transistor. The patterning process may be similar to that described in step 110, and the details thereof are omitted herein for the sake of brevity.

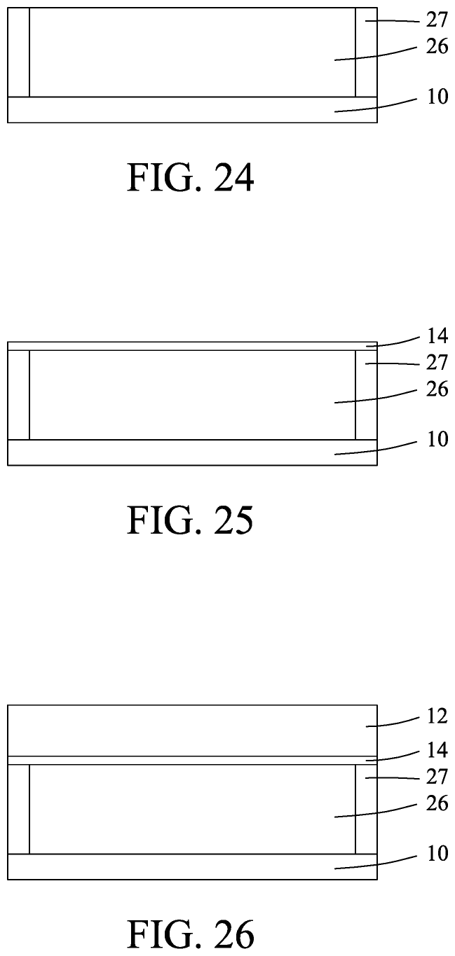

Referring to FIGS. 20 and 24, next, the method 2000 proceeds to step 2008, where a supplementary dielectric material layer 27 is first formed on the first dielectric layer 10 and the channel layer 26, and a CMP process or other suitable process is then performed to planarize a top surface of the supplementary dielectric material layer 27 so as to expose the channel layer 26. The materials and techniques used for forming the supplementary dielectric material layer 27 are similar to those used for forming the first dielectric layer 10 as described in step 102, and the details thereof are omitted herein for the sake of brevity.

Referring to FIGS. 20 and 25, the method 2000 then proceeds to step 2010, where a gate dielectric material layer 14 is formed on the channel layer 26 and the supplementary dielectric material layer 27. The materials and techniques used for forming the gate dielectric material layer 14 may be similar to those used for forming the gate dielectric material layer 14 as described in step 106, and the details thereof are omitted herein for the sake of brevity.

Referring to FIGS. 20 and 26, the method 2000 then proceeds to step 2012, where a gate material layer 12 is formed on the gate dielectric material layer 14. The materials and techniques used for forming the gate material layer 12 may be similar to those used for forming the gate material layer 12 as described in step 104, and the details thereof are omitted herein for the sake of brevity.

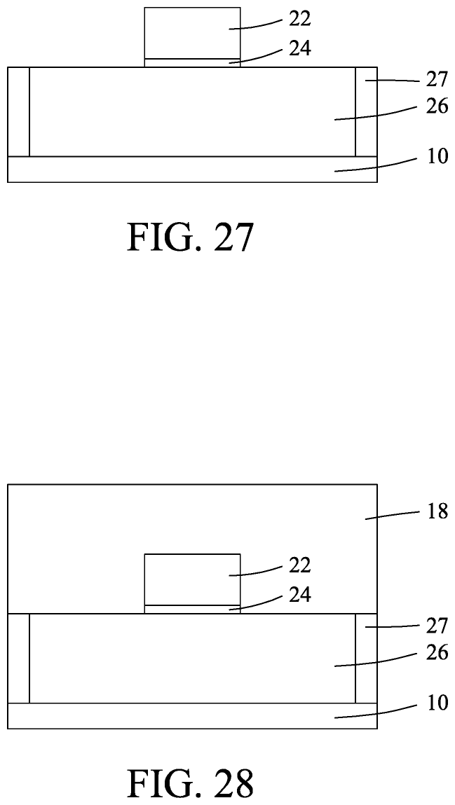

Referring to FIGS. 20 and 27, the method 2000 then proceeds to step 2014, where a patterning process is conducted so as to form a pattern for the gate material layer 12 and the gate dielectric material layer 14 shown in FIG. 26. As a result, a patterned gate material layer and a patterned gate dielectric material layer are formed to serve as the gate electrode 22 and the gate dielectric 24 (i.e., the gate stack) of the transistor, respectively. The patterning process may be similar to that as described in step 110, and the details thereof are omitted herein for the sake of brevity.

Afterward, referring to FIGS. 20 and 28, the method 2000 proceeds to step 2016, where a second dielectric material layer 18 is formed on the supplementary dielectric material layer 27, the gate electrode 22, the gate dielectric 24, and the channel layer 26. The materials and techniques used for forming the second dielectric material layer 18 are similar to those used for forming the first dielectric layer 10 as described in step 102, and the details thereof are omitted herein for the sake of brevity. In some embodiments, the second dielectric material layer 18 may be a single material layer. In alternative embodiments, the second dielectric material layer 18 may be constituted by multiple films made of different materials that are suitable for forming the first dielectric layer 10. It is noted that a CMP process or another suitable process may be performed to planarize a top surface of the second dielectric material layer 18.

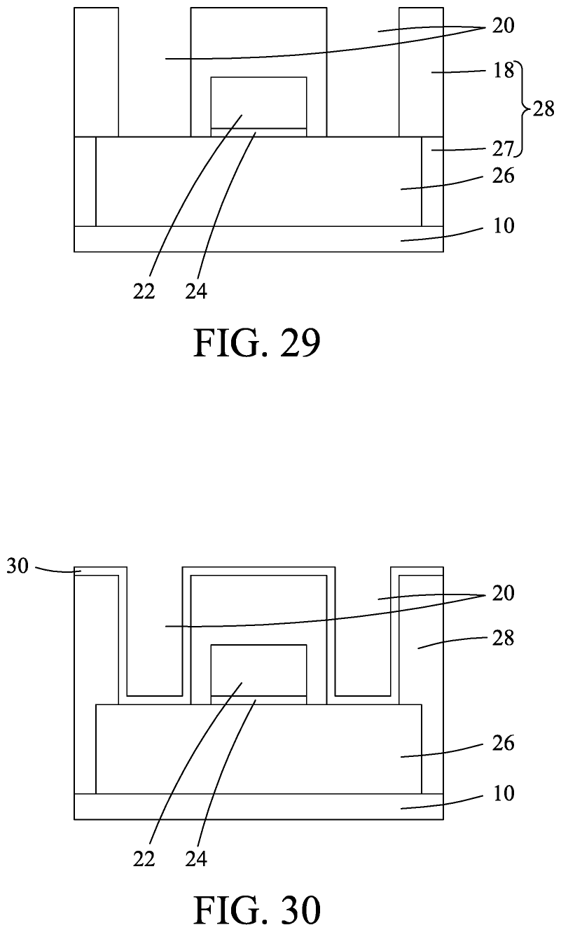

Referring to FIGS. 20 and 29, the method 2000 then proceeds to step 2018, where a patterning process is conducted to pattern the second dielectric material layer 18. The patterning process in this step may be implemented using a technique as described in step 110 such that portions of the second dielectric material layer 18 are removed in a top-down direction. As a result, two trenches 20 are formed in the second dielectric material layer 18, and the supplementary dielectric material layer 27 and the second dielectric material layer 18 together form the second dielectric layer 28.

It is noted that the trenches 20 are formed for receiving U-shaped blocking layers, U-shaped buffer layers, and source/drain contacts, and a minimum distance between a respective one of the buffer layers is to be maintained in order for the resulting transistor to function normally. Based on different processes and design rules, the minimum distance may be in a range between about 2 nm to about 5 nm, although a slightly larger or smaller distance may also be adopted. As such, the trenches 20 are formed such that the resulting buffer layers maintain the minimum distance.

Referring to FIGS. 20 and 30, the method 2000 then proceeds to step 2020, where a blocking material layer 30 is conformally formed on the second dielectric layer 28 and the channel layer 26 along inner surfaces of the trenches 20. The materials and techniques used for forming the blocking material layer 30 may be similar to those used for forming the blocking material layer 30 as described in step 116, and the details thereof are omitted herein for the sake of brevity. In some embodiments, a thickness of the blocking material layer 30 may be similar to that of the blocking material layer 30 as described in step 116 (e.g., ranging from about 1 nanometer to about 10 nanometers), and the details thereof are omitted herein for the sake of brevity.

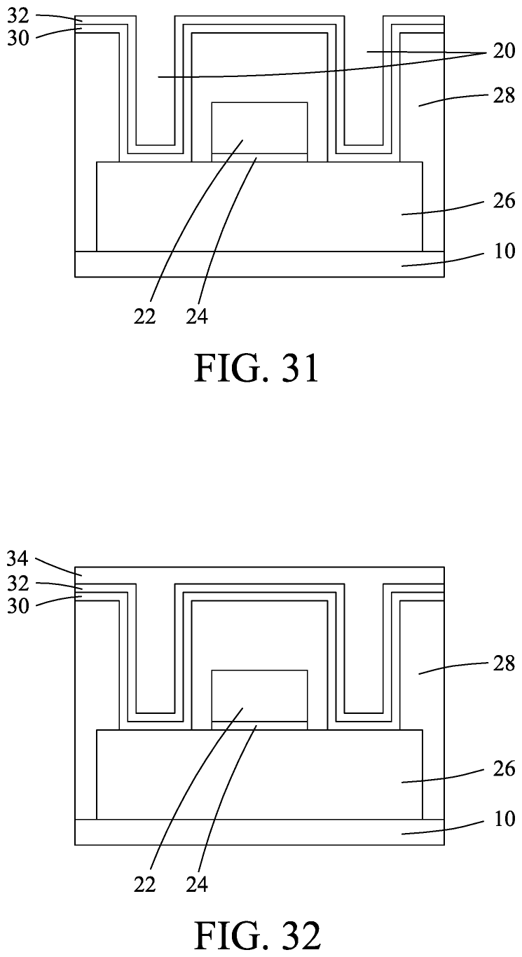

Referring to FIGS. 20 and 31, the method 2000 then proceeds to step 2022, where a buffer material layer 32 is conformally formed on the blocking material layer 30 along surfaces of the blocking material layer 30 in the trenches 20. The materials and techniques used for forming the buffer material layer 32 may be similar to those used for forming the buffer material layer 32 as described in step 118, and the details thereof are omitted herein for the sake of brevity. In some embodiments, a thickness of the buffer material layer 32 may be similar to that of the buffer material layer 32 as described in step 118 (e.g., ranging from about 1 nanometer to about 10 nanometers), and the details thereof are omitted herein for the sake of brevity.

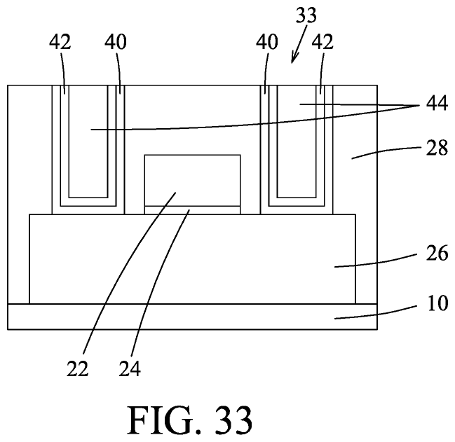

Referring to FIGS. 20 and 32, the method 2000 then proceeds to step 2024, where a metal layer 34 is formed on the buffer material layer 32 to fill the trenches 20 shown in FIG. 31. The materials and techniques used for forming the metal layer 34 may be similar to those used for forming the metal layer 34 as described in step 120, and the details thereof are omitted herein for the sake of brevity.

Referring to FIGS. 20, 32 and 33, the method 2000 then proceeds to step 2026, where a planarization process such as a CMP process, or another suitable technique is conducted to remove excesses of the blocking material layer 30, the buffer material layer 32 and the metal layer 34. In some embodiments, the CMP process may be performed to the extent that the second dielectric layer 28 is exposed. The blocking material layer 30 remaining in the trenches 20 may serve as two U-shaped blocking layers 40 of a transistor 33, the buffer material layer 32 remaining in the trenches 20 may serve as two U-shaped buffer layers 42 of the transistor 33, and the metal layer 34 remaining in the trenches 20 may serve as two source/drain contacts 44 of the transistor 33. In this manner, the source/drain contacts 44 are formed in the trenches 20 so as to permit each of the source/drain contacts 44 to be surrounded by a respective one of the buffer layers 42 and a respective one of the blocking layers 40.

In the semiconductor device as shown in FIG. 33, the gate dielectric 24 is located over the channel layer 26 and between the source/drain contacts 44, and the gate electrode 22 is located over the gate dielectric 24 (i.e., the source/drain contacts 44 are disposed at opposite sides of the gate dielectric 24 and the gate electrode 22). That is to say, the transistor 33 shown in FIG. 33 has a front-contacted, front-gate structure. Additionally, in the semiconductor device as shown in FIG. 33, the transistor 33 includes the two U-shaped buffer layers 42 that are formed to surround the two source/drain contacts 44, respectively, and the two U-shaped blocking layers 40 that are formed to surround the two U-shaped buffer layers 42, respectively, in a manner similar to that of the transistor 11 as shown in FIG. 12.

Thus, the method 2000 for manufacturing the semiconductor device shown in FIG. 33 is completed. In alternative embodiments, other suitable methods may also be applied for forming the semiconductor device shown in FIG. 33. In yet alternative embodiments, additional features may be added to the semiconductor device shown in FIG. 33, and some features of the semiconductor device shown in FIG. 33 may be modified, replaced, or eliminated without departing from the spirit and scope of the present disclosure.

In some embodiments, the method for forming a semiconductor device according to this disclosure may be integrated with processes in a FEOL portion of semiconductor device fabrication. That is to say, the transistor of the semiconductor device that is fabricated in the BEOL portion as exemplarily shown in FIGS. 12, 19 and 33 may be located over other another semiconductor device that is fabricated in the FEOL portion.

In this disclosure, interface engineering at source/drain for a transistor is proposed, where buffer layers are respectively provided around the source/drain contacts to separate the source/drain contacts from the channel layer, and blocking layers are respectively provided around the buffer layers to separate the buffer layers from the channel layer. In such structure, hydrogen gas and/or free hydrogen atoms (which may be introduced or generated in various processes, such as deposition processes including CVD, annealing, etc.) from the source/drain contacts or other devices may be prevented from diffusing into the channel layer. In addition, the blocking layers may prevent elements of the buffer layers from intermixing with the channel layers, that is to say, intermixing between the buffer layers and the channel layer may be suppressed. Moreover, the blocking layers may prevent ions from diffusing from the buffer layers into the channel layers, that is to say, inter-diffusion between the buffer layers and the channel layer may also be suppressed. In this way, a chemical distribution of the channel layer can be maintained as intended, device stability can thus be improved during a thermal-related process in semiconductor device fabrication, and device performance degradation after the thermal-related process can thus be mitigated.

In accordance with some embodiments of the present disclosure, a semiconductor device includes a gate electrode, a gate dielectric located over the gate electrode, a channel layer including a semiconductor material, and located over the gate dielectric, blocking layers located over the channel layer, covering portions of channel layer, and spaced apart from each other, buffer layers respectively located over the blocking layers and respectively surrounded by the blocking layers, and source/drain contacts respectively located over the buffer layers and respectively surrounded by the buffer layers. The buffer layers include a material that receives hydrogen.

In accordance with some embodiments of the present disclosure, the blocking layers include titanium nitride, tantalum nitride, titanium, nickel, aluminum, ruthenium, or combinations thereof.

In accordance with some embodiments of the present disclosure, each of the buffer layers includes an interconnecting buffer section that is in contact with a lower surface of a corresponding one of the source/drain contacts, and two extending buffer sections that respectively extend from two opposite ends of the interconnecting buffer section to be respectively in contact with two opposite surfaces of the corresponding one of the source/drain contacts.

In accordance with some embodiments of the present disclosure, each of the blocking layers includes an interconnecting blocking section that is in contact with the channel layer and the interconnecting buffer section of a corresponding one of the buffer layers, and two extending blocking sections that respectively extend from two opposite ends of the interconnecting blocking section to be respectively in contact with the extending buffer sections of the corresponding one of the buffer layers.

In accordance with some embodiments of the present disclosure, the buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

In accordance with some embodiments of the present disclosure, the semiconductor material includes amorphous silicon, crystalline silicon, indium zinc oxide, indium gallium oxide, indium gallium zinc oxide, tungsten-doped indium oxide, tungsten-doped indium zinc oxide, indium gallium zinc tin oxide, zinc oxide, indium tin oxide, gallium oxide, indium oxide, or combinations thereof.

In accordance with some embodiments of the present disclosure, the semiconductor device further includes additional buffer layers that are respectively located over the buffer layers, that respectively surround the source/drain contacts, and that are respectively in contact with the source/drain contacts.

In accordance with some embodiments of the present disclosure, the additional buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

In accordance with some embodiments of the present disclosure, the semiconductor device further includes additional blocking layers that are respectively located over the buffer layers, that are respectively surrounded by the buffer layers, and that respectively surround the additional buffer layers.

In accordance with some embodiments of the present disclosure, the additional blocking layers include titanium nitride, tantalum nitride, titanium, nickel, aluminum, ruthenium, or combinations thereof.

In accordance with some embodiments of the present disclosure, a semiconductor device includes a channel layer including a semiconductor material, a gate stack, source/drain contacts located over the channel layer, and disposed at opposite sides of the gate stack, buffer layers respectively surrounding the source/drain contacts and including a material that receives hydrogen, and blocking layers respectively located over the channel layer and respectively surrounding the buffer layers. The gate stack includes a gate dielectric that is located over the channel layer, and a gate electrode that is located over the gate dielectric.

In accordance with some embodiments of the present disclosure, the blocking layers include titanium nitride, tantalum nitride, titanium, nickel, aluminum, ruthenium, or combinations thereof.

In accordance with some embodiments of the present disclosure, the buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

In accordance with some embodiments of the present disclosure, the semiconductor material includes amorphous silicon, crystalline silicon, indium zinc oxide, indium gallium oxide, indium gallium zinc oxide, tungsten-doped indium oxide, tungsten-doped indium zinc oxide, indium gallium zinc tin oxide, zinc oxide, indium tin oxide, gallium oxide, indium oxide, or combinations thereof.

In accordance with some embodiments of the present disclosure, a method for manufacturing a semiconductor device includes forming a channel layer that includes a semiconductor material, forming a gate stack including a gate electrode and a gate dielectric such that the gate dielectric is disposed between the gate electrode and the channel layer, forming blocking layers on the channel layer such that the blocking layers are spaced apart from each other, forming buffer layers on the blocking layers, and forming source/drain contacts respectively on the buffer layers. The buffer layers including a material that receives hydrogen.

In accordance with some embodiments of the present disclosure, the blocking layers include titanium nitride, tantalum nitride, titanium, nickel, aluminum, ruthenium, or combinations thereof.

In accordance with some embodiments of the present disclosure, the buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

In accordance with some embodiments of the present disclosure, the gate electrode and the gate dielectric are formed before formation of the channel layer.

In accordance with some embodiments of the present disclosure, the buffer layers and the source/drain contacts are formed by, after forming the channel layer, forming a dielectric layer on the channel layer, forming trenches in the dielectric layer to expose the channel layer, forming blocking layers respectively in the trenches, forming buffer layers respectively on the blocking layers and respectively in the trenches, and forming the source/drain contacts respectively in the trenches so as to permit each of the source/drain contacts to be surrounded by a respective one of the buffer layers and a respective one of the blocking layers.

In accordance with some embodiments of the present disclosure, the gate stack is formed by, after forming the channel layer, forming a gate dielectric material layer on the channel layer, forming a gate material layer on the gate dielectric material layer, and conducting a patterning process on the gate material layer and the gate dielectric material layer so as to form the gate electrode and the gate dielectric.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a gate electrode;
a gate dielectric located over the gate electrode;
a channel layer including a semiconductor material, and located over the gate dielectric;
blocking layers located over the channel layer, covering portions of channel layer, and spaced apart from each other;
buffer layers respectively located over the blocking layers and respectively surrounded by the blocking layers, the buffer layers including a material that receives hydrogen; and
source/drain contacts respectively located over the buffer layers and respectively surrounded by the buffer layers.

2. The semiconductor device of claim 1, wherein the blocking layers include titanium nitride, tantalum nitride, titanium, nickel, aluminum, ruthenium, or combinations thereof.

3. The semiconductor device of claim 1, wherein each of the buffer layers includes an interconnecting buffer section that is in contact with a lower surface of a corresponding one of the source/drain contacts, and two extending buffer sections that respectively extend from two opposite ends of the interconnecting buffer section to be respectively in contact with two opposite surfaces of the corresponding one of the source/drain contacts.

4. The semiconductor device of claim 3, wherein each of the blocking layers includes an interconnecting blocking section that is in contact with the channel layer and the interconnecting buffer section of a corresponding one of the buffer layers, and two extending blocking sections that respectively extend from two opposite ends of the interconnecting blocking section to be respectively in contact with the extending buffer sections of the corresponding one of the buffer layers.

5. The semiconductor device of claim 1, wherein the buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

6. The semiconductor device of claim 1, wherein the semiconductor material includes amorphous silicon, crystalline silicon, indium zinc oxide, indium gallium oxide, indium gallium zinc oxide, tungsten-doped indium oxide, tungsten-doped indium zinc oxide, indium gallium zinc tin oxide, zinc oxide, indium tin oxide, gallium oxide, indium oxide, or combinations thereof.

7. The semiconductor device of claim 1, further comprising additional buffer layers that are respectively located over the buffer layers, that respectively surround the source/drain contacts, and that are respectively in contact with the source/drain contacts.

8. The semiconductor device of claim 7, wherein the additional buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

9. The semiconductor device of claim 7, further comprising additional blocking layers that are respectively located over the buffer layers, that are respectively surrounded by the buffer layers, and that respectively surround the additional buffer layers.

10. The semiconductor device of claim 9, wherein the additional blocking layers include titanium nitride, tantalum nitride, titanium, nickel, aluminum, ruthenium, or combinations thereof.

11. A semiconductor device, comprising:
a channel layer including a semiconductor material;
a gate stack including a gate dielectric that is located over the channel layer, and a gate electrode that is located over the gate dielectric;
source/drain contacts located over the channel layer, and disposed at opposite sides of the gate stack;
buffer layers respectively surrounding the source/drain contacts, and including a material that receives hydrogen; and
blocking layers respectively located over the channel layer, and respectively surrounding the buffer layers.

12. The semiconductor device of claim 11, wherein the blocking layers include titanium nitride, tantalum nitride, titanium, nickel, aluminum, ruthenium, or combinations thereof.

13. The semiconductor device of claim 11, wherein the buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

14. The semiconductor device of claim 11, wherein the semiconductor material includes amorphous silicon, crystalline silicon, indium zinc oxide, indium gallium oxide, indium gallium zinc oxide, tungsten-doped indium oxide, tungsten-doped indium zinc oxide, indium gallium zinc tin oxide, zinc oxide, indium tin oxide, gallium oxide, indium oxide, or combinations thereof.

15. A method for manufacturing a semiconductor device, comprising:
forming a channel layer that includes a semiconductor material;
forming a gate stack including a gate electrode and a gate dielectric such that the gate dielectric is disposed between the gate electrode and the channel layer;
forming blocking layers on the channel layer such that the blocking layers are spaced apart from each other;
forming buffer layers on the blocking layers, the buffer layers including a material that receives hydrogen; and
forming source/drain contacts respectively on the buffer layers.

16. The method of claim 15, wherein the blocking layers include titanium nitride, tantalum nitride, titanium, nickel, aluminum, ruthenium, or combinations thereof.

17. The method of claim 15, wherein the buffer layers include indium oxide, indium zinc oxide, indium tin oxide, zinc tin oxide, indium gallium zinc oxide, gallium oxide, crystalline indium gallium zinc oxide, a semiconductor material including indium, gallium, zinc, silicon, and oxide, a metal compound including zirconium and nickel, zinc oxide, tungsten-doped indium oxide, or combinations thereof.

18. The method of claim 15, wherein the gate electrode and the gate dielectric are formed before formation of the channel layer.

19. The method of claim 15, wherein the blocking layers, the buffer layers and the source/drain contacts are formed, after forming the channel layer, by:
forming a dielectric layer on the channel layer;
forming trenches in the dielectric layer to expose the channel layer;
forming blocking layers respectively in the trenches;
forming buffer layers respectively on the blocking layers and respectively in the trenches; and
forming the source/drain contacts respectively in the trenches so as to permit each of the source/drain contacts to be surrounded by a respective one of the buffer layers and a respective one of the blocking layers.

20. The method of claim 15, wherein the gate stack is formed, after forming the channel layer, by:
forming a gate dielectric material layer on the channel layer;
forming a gate material layer on the gate dielectric material layer; and
conducting a patterning process on the gate material layer and the gate dielectric material layer so as to form the gate electrode and the gate dielectric.
